(19) United States
(12) Patent Application Publication
(10) Pub. No.: US 2019/0220106 A1
(43) Pub. Date: Jul. 18, 2019

(54) Object Tracking System and Method

(71) Applicant: KODAMA LTD., London (GB)

(72) Inventors: Charles LECLERCQ, Paris (FR); Antoni PAKOWSKI, London (GB)

(73) Assignee: Kodama Ltd., London (GB)

(21) Appl. No.: 16/312,911

(22) PCT Filed: Jun. 22, 2017
(86) PCT No.: PCT/GB2017/051834

§ 371 Date: Dec. 21, 2018

(30) Foreign Application Priority Data
Jun. 22, 2016 (GB) 1610943.1
Apr. 24, 2017 (GB) 1706490.8
May 5, 2017 (GB) 1707271.1

(51) Int. Cl. G06F 3/0346; G06F 3/0354; G06F 3/038; G01D 5/14; G01R 33/02; G06K 19/07

(52) U.S. Cl. CPC G06F 3/0346; G06F 3/0354; G06F 3/038; A63F 13/211; G01R 33/0206; G06K 19/0723; G06F 2203/0384; G01D 5/14

(57) ABSTRACT

A method is provided for tracking the position of an object (150). The method comprises receiving magnetic field data from one or more sensors (122) disposed within a base (120). The sensors are configured to detect the magnetic field emanating from a magnet (112) on or within the object or an object module (150a) housed in the object. The method further comprises determining an actual position of the object relative to the base based on the magnetic field data from the sensors. The method also comprises generating a corresponding virtual position of the object based on the magnetic field data for displaying electronically. A system for carrying out the method is also provided.

### TECHNICAL FIELD

The present invention relates to a system and method for tracking a position of an object that comprises a magnet with respect to a detector and generating a virtual representation thereof. In particular, the present invention relates to use of a magnetic position sensor to determine a physical position of the object, and generating a corresponding virtual representation of the position of the object.

### BACKGROUND TO THE INVENTION

The GPS (Global Positioning System) is an array of satellites that orbit the Earth and enable people on the Earth to identify their geographic location in longitude, latitude and elevation, to an accuracy of between about 100 to 10 meters. Accuracy can be improved for specialist military, to about 1 m. GPS cannot enable the determination of the location of a GPS receiver more accurately. GPS also does not work very well (or at all) indoors.

Various indoor devices use sensors that can detect the positions of objects. For example, TV remote controls and gaming consoles employ optical (e.g. infrared or pixel-based) sensors to detect a signal from a transmitter in a controller. Such systems can be used to provide location three-dimensional (3D) position information, but are susceptible to poor performance in poor environmental conditions such as low light levels and require a clear line of sight between the emitter and the sensor to function. Furthermore, known systems that detect hand/body movements are expensive and thus their use is prohibitive in some circumstances.

There may be instances when a system providing better accuracy to smaller distances is required, particularly indoors without the inherent problems of optical systems. The present invention has been devised with the foregoing in mind.

### SUMMARY OF THE INVENTION

“Object” as used in the claims and throughout this specification means an object having an integral or removable magnet that is e.g. housed in a magnet/object module that is an insertable into the object. References to a “magnet” are to be interpreted as meaning any source of magnetic field. Anything that provides a magnetic field can be used.

In accordance with a first aspect of the present invention there is provided a method for tracking the position of an object as defined in claim 1.

The method may further comprise generating a virtual environment comprising a virtual base corresponding to the base, and displaying, in the virtual environment, a corresponding virtual object at the generated virtual position of the object relative to a virtual base.

In an embodiment, the method further comprises reading an electronic ID associated with the object and generating a signal representative of the identity of a corresponding ID of the virtual object.

The method may further comprise, based on the signal representative of the ID of the virtual object, displaying a virtual object having one or more unique characteristics.

Generating the virtual object and/or virtual position of the object may be performed in real time or near real time, or otherwise.

In an embodiment, when the object is moved relative to the base, the method may comprise determining a new actual position of the object relative to the base and updating the virtual position of the virtual object relative to the virtual base.

In accordance with a second aspect of the present invention there is provided a system for tracking the position of an object or as defined in claim 7.

In accordance with further aspects of the invention there is provided an object module as defined in claim 20 or 23. In accordance with yet further aspects of the invention there is provided an object as defined in claim 22 or 23.

The following apply to all aspects and embodiments of the invention.

The object may be a toy or a controller e.g. a games controller.

In a preferred embodiment, the magnet is comprised in an object module (or magnet module) that is removably receivable within or on the object. The object module may be detachably attachable in or to the object e.g. by clicking, snap-fitting or screwing therein. The object module may be detachably attachable in or to other electronic components or accessories for use with the system. It is an advantage that an object module is interchangeable between different components of the system, and that additional objects, accessories etc. may be added to the system and are compatible with the existing object module(s).

The object module may comprise the transceiver, or the transceiver may be provided in the base.

An electronics hub may be provided comprising one or more of a power source for powering the object module, a communications device for electronically communicating with the object module and/or an external device, and a processor for processing magnetic field strength data received from the one or more sensors. The object module(s) may be receivable or dockable in or on e.g. within recesses provided in the hub.

The object or object module may also comprise an accelerometer and/or a gyroscope. The object or object module may further comprise an electronic ID or ID tag. The object, object module, hub and/or base may further comprise a reader for reading the electronic ID or ID tag. For example, the object may comprise an electronic ID or ID tag and the base and/or object module may further comprise a reader for reading the electronic ID or ID tag. The object module, base and/or hub may comprise a processor for processing magnetic field strength data received from the one or more sensors. The object and/or object module may be configured for wireless communication with the base, hub and/or an external electronic/computing device.

The object or object module may comprise one or more of: an electromagnet, an accelerometer and a gyroscope. It may instead/also comprise one or more of a Bluetooth device, a transistor circuit to manage duty cycle of the electromagnet, a step-up chip to raise the voltage delivered to the electromagnet, a processor to manage the signals and turn things on and off as required, a battery, connectors for battery charging and connection to an object and an ID e.g. RF reader to recognize external hardware such as objects. The object or object module may comprise a sensor e.g. a magnetometer.

The object or object module may do one or more of the following (non-exhaustive list):
send data from a sensor (e.g. an accelerometer and/or gyroscope) to the external device e.g. via wireless e.g. Bluetooth;
initiate the on board electromagnet when requested by the external device via Bluetooth, or initiate the magnet based on a timer;
recognise an external object e.g. a toy e.g. via RFID;
send data from hardware (e.g. a button or joystick on a game pad) that it plugs into;
power an external device that it is plugged into.

However, the subcomponents of the system can instead directly connect to the external device. The base may be configured to accumulate the data and send it to the external device. The computation/processing of data may therefore take place in the base, before the position data is sent to the external device, or the system may send raw data directly to the external device where the calculations/processing may be performed remotely. Alternatively the subcomponents may each send their data independently to the external device. Importantly, for embodiments where processing is performed remotely on the external device, this advantageously enables the system to be manufactured at a very low cost. The more intense computing is then performed on a user's external device such as a laptop or tablet which has no problem performing calculations of that kind, and avoids the need to put an expensive computational unit into the system.

In an embodiment, the object itself contains the magnet and may be integrally formed with the magnet. The object may comprise the transceiver. The object may also comprise an accelerometer and/or a gyroscope. I.e. in an embodiment, the magnet is integral with the object. In another embodiment, the magnet is insertable into and/or removable from the object (which in this embodiment does not have a magnet). The magnet may be housed in an object module (or a magnet module) that can be placed in or on and/or removed from the object. As such, references to an “object” as used throughout are to be interpreted as meaning any component that comprises a magnet—i.e. it could be the object module, the combination of the object module when inserted into an object, or the object where the magnet is an integral part thereof.

In an embodiment, the magnet is or comprises an electromagnet. The object or object module may further comprise a microcontroller and a switching element operable to control electrical power delivered to the electromagnet, wherein the microcontroller is in data communication with the transceiver. The microcontroller is preferably operable to control the switching element based on commands received from the transceiver. The transceiver may be provided in or on the base or in the object module.

The use of electromagnets is convenient since it enables multiple objects or object modules each having an electromagnet to be used at the same time since each can be programmed to operate at a different frequency in order that the objects can be distinguished from each other. The electromagnet can be used under AC operation, where different objects or object modules are programmed to operate at different frequencies, or under DC operation where the magnets are simply turned on and off in sequence so that they can be sensed by the sensor(s) independently. The duty cycle of the on/off sequence can be varied in duration depending on the number of objects/object modules to be sensed. This electromagnet flashing can be controlled by a signal received from the external device.

In accordance with any aspect or embodiment of the invention, the base may be a planar sheet, mat or container for housing the constituent components. It may be undecorated or may be provided with markings, either for use with a particular application or for decoration. The nature of the interaction between the object/object module and base/mat is dictated by the digital content chosen by the user—any environment, interaction or game may be experienced. Neither the mat/base or object/object module limits the interaction that is possible. The mat/base may be rigid or part-rigid, or flexible or part-flexible. The mat may be manufactured such that it can be rolled or folded. The mat may comprise a plurality of rigid or semi-rigid sections joined by flexible portions allowing the mat to be rolled or folded.

The system may further comprise an electronic display for displaying a generated virtual environment representative of the base and/or displaying the virtual position of the object or object module relative to a virtual base in the virtual environment. In an embodiment, when the object/or object module is moved relative to the base, a new actual position of the object/or object module relative to the base may be determined and the virtual position of the virtual object/or object module relative to the virtual base may be updated on the display. Generating the visual representation of the position of the object/or object module may be performed in real time or near real time, or otherwise.

The object, object module or hub may comprise an antenna operable to receive a wireless command signal from the transceiver. The transceiver may receive data from the one or more sensors and the reader via a multiplexer to selectively read an output signal from any one of the plurality of sensors or the reader. The system may comprise a plurality of objects or object modules that may be simultaneously tracked. The objects may each be represented/displayed simultaneously in the virtual environment.

The base may be substantially planar. The one or more sensors may be arranged on or within the base to define a “tracking area” on the base. A “tracking volume” may be defined by the tracking area and a tracking radius of the sensor in a direction normal to the surface of the base. The one or more sensors may comprise at least two or three sensors. Where a plurality of sensors is provided, these may be arranged in a geometric pattern or array. The plurality of sensors may be or comprise an array of sensors arranged on a rectangular lattice. The plurality of sensors may be or comprise an array of sensors arranged on a triangular lattice. The outer boundary of the array may define the tracking area. The tracking area may have lateral dimensions from between about 0 cm to 40 cm, but can be much larger in some embodiments.

In another embodiment, the sensors may all be located in the hub. In that embodiment the hub acts as a base and does not then provide a flat surface with relation to which objects can be moved. Instead, a user can move objects in free space all around the bub. In an embodiment, the hub could be mounted on a stand or other support, to elevate it above the ground or desk surface on which a mat might have been used. That advantageously provides a tracking volume of substantially 360°. In some embodiments the hub is not needed at all, and basic interactions or games can be experienced based on just moving the object with object module in 3D space, based on data from the accelerometer and gyroscope in the object module. It is also possible to experience interactions of an object/object module with a mobile phone or other electronic device.

In an embodiment, one or more of the object modules may also comprise a sensor e.g. a magnetometer. This enables each object module (which also contains a magnet) to determine its position relative to other object modules. This can be achieved, where an electromagnet is used, as the electromagnet is switched on and off as described above. Advantageously, even if the position of the object module in space is not known (e.g. if a base/mat is not being used), the distance between different objects can be determined. And if multiple objects are present, a form of trilateration can be performed.

Particularly in embodiments where the sensors are located in the hub, but also in other embodiments, the arrangement of the sensors themselves does not need to be planar.

The system may further comprise a camera or camera module in data communication with the transceiver to provide an input for the point of view and perspective of the generated virtual environment. The camera module may be in wireless data communication with the transceiver and may comprise a microcontroller and an inertial measurement unit (IMU) (or separate accelerometer and/or gyroscope). The camera module may be moved manually or e.g. by a robot, and the movement may be analysed by the IMU and sent to the transceiver wirelessly via the RF transceiver. The camera data stream may comprise the position of the camera relative to the base, the yaw, pitch and roll of the IMU. There may additionally or instead be provided a microphone in data communication with the transceiver to provide data e.g. a microphone data stream to the transceiver.

Activating the electromagnet may comprise operating one or more switching elements. The electromagnets of each object may be activated and deactivated periodically such that only one electromagnet is activated at any one time. In an embodiment, one or more of the sensors may have a minimum detectable field of less than the earth's magnetic field (about 10-60 microtesla, although depending on whether AC operation or DC operation is used, this may vary).

In an embodiment, the system further comprises an electronic device with a display for displaying the generated virtual position and optionally or preferably for displaying the generated virtual environment. All of the calculations can occur on the external device 160 e.g. via an app, a programme, or a web application. Alternatively, the calculations can be performed by a processor in the base or hub.

The transceiver may be in wireless data communication with the microcontroller of the object and, optionally or preferably, the wireless data communication is via Bluetooth.

According to aspects and embodiments, an object module, base/mat and or hub can be paired by Bluetooth. The ID of a given object module is then added to a list of object modules to connect to. Object modules can be paired when they are physically connected to the hub, through the charging ports. The object modules cannot be in pairing mode constantly because this could lead to a problem of object modules connecting to someone else's system. However, another user can bring his objects and object modules to connect/pair to the hub/system—he only has to plug and unplug his object modules into the hub and they will also be paired. This also advantageously avoids the problem of having to go into the app to connect new trackers.

The object module may be configured to connect directly with a smartphone or tablet (external device) independently from use via the hub/mat.

The electronic ID may be stored in a radio frequency electronic ID (RFID) tag or a near-field communication (NFC) tag. (Alternatively, the ID of the object may be conveyed through a hard connection, such as a set of pins. RFID is convenient because it allows objects to be identified at low cost, and enables encryption of data content. It also gives an open framework for another input for future hardware such as various controllers. The RFID reader in the object module, object, mat or hub may also be used to “wake up” the object module when it is placed into an object module.

In an embodiment, the plurality of sensors is arranged to and is operable for determining a position of the object in 3D space. The data received from the plurality of sensors may be or comprise a three dimensional magnetic field vector. It is a particular advantage of aspects and embodiments of the invention that the position of the object in 3D can be determined. Prior art systems tend only to work in 2D, and require the object to be located and move along or very close to the sensors.

Determining the position of the object relative to the base may comprise converting the data from the plurality of sensors into a three dimensional position vector relative to the position of the sensors and calculating the position of the object relative to the base by multilateration e.g. trilateration.

In an embodiment, the tracking of the virtual object on a display is recorded.

In another aspect of the invention, there is provided a computer program configured to, when executed on a computing device, cause the computing device to perform the method of the first aspect.

Aspects and embodiments of the invention may be implemented on a computer. There may be provided a computer program, which when run on a computer, causes the computer to perform any method disclosed herein. The computer program may be a software implementation, and the computer may be considered as any appropriate hardware, including a digital signal processor, a microcontroller, and an implementation in read only memory (ROM), erasable programmable read only memory (EPROM) or electronically erasable programmable read only memory (EEPROM), as non-limiting examples. The software implementation may be an assembly program.

The computer program may be provided on a computer readable medium, which may be a physical computer readable medium, such as a disc or a memory device, or may be embodied as a transient signal. Such a transient signal may be a network download, including an internet download.

According to this another aspect there is provided software or a computer program configured to, when executed on a computing device, cause the computing device to perform the method according to the first aspect.

Aspects and embodiments of the invention can advantageously be used in a large number of different applications, from playing games to creating virtual/digital works, to controlling real and virtual objects. Aspects and embodiments of the invention provide a real-time tracking system where a user is in principle free to move the object/object module wherever he or she wishes (within the confines of the measurement range) and the movement will be interpreted and processed and presented in a virtual environment.

Features of the aspects and embodiments described above and below may be used interchangeably and/or in combination, even if not expressly stated.

### BRIEF DESCRIPTION OF DRAWINGS

Aspects and embodiments of the invention will now be discussed with reference to the figures of the accompanying drawings, in which:

FIGS. 1a and 1b show schematic representations of a system;

FIGS. 2(a)-(e) show example mats for use with the system of FIG. 1;

FIGS. 3, 4, and 10-12 show schematic diagrams of exemplary objects;

FIGS. 5 and 7(a) to (c) show schematic diagrams of exemplary bases;

FIG. 6 is a schematic circuit diagram of the base;

FIGS. 8 and 9 show schematic representations of a system;

FIGS. 13 and 14 show alternative uses of the object module;

FIG. 15 shows how the object modules are received within a hub;

FIG. 16 shows a schematic representation of an object;

FIGS. 17, 18 and 19a show prototype tracking systems;

FIG. 19b shows an example of a generated virtual environment;

FIG. 20a shows the principal circuit components of the camera module;

FIG. 20b illustrates a process for using the camera module in conjunction with the system;

FIG. 21 shows a flow diagram illustrating a method of tracking the position of an object relative to a base;

FIG. 22 shows a flow diagram illustrating a method of determining the position of the object relative to a base; and

FIG. 23 shows a flow diagram illustrating operation of the system.

### DETAILED DESCRIPTION OF EMBODIMENTS OF THE INVENTION

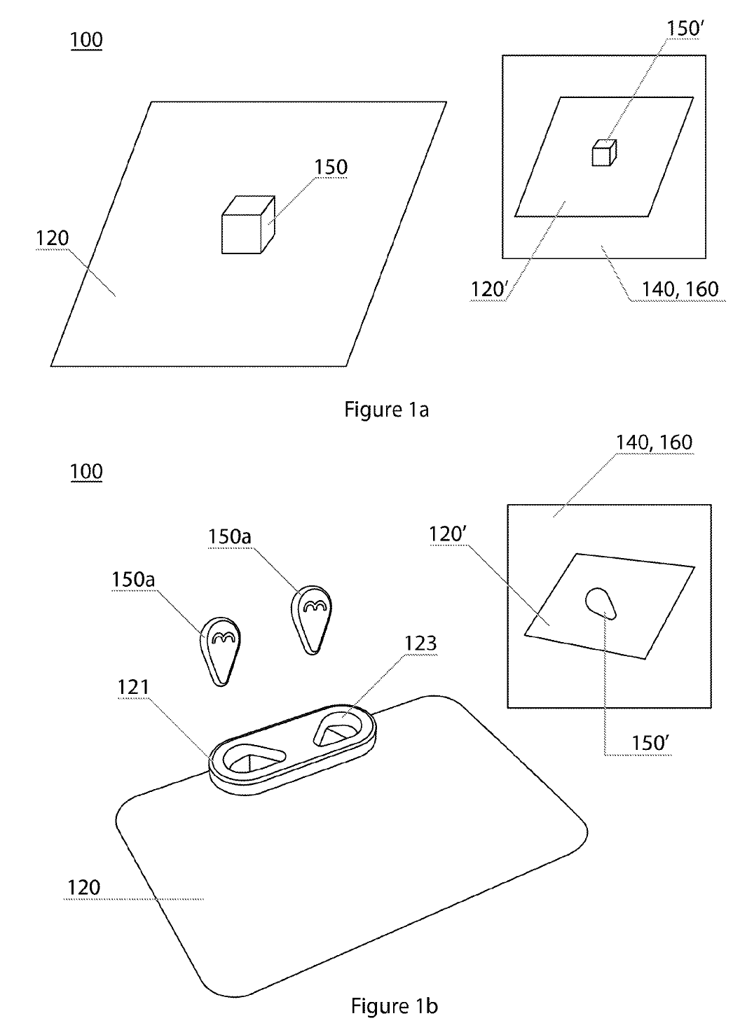

FIG. 1a shows a tracking system 100 according to a first embodiment of the invention. The system 100 comprises an object 150 and a mat, base or platform 120. The base 120 is provided for use with the object 150 to track the position of the object 150 relative to the base 120. A computer generated virtual environment 140, for display on an external computing device 160, is also provided in which the position of the object 150 relative to the base 120 can be displayed as a corresponding virtual representation of the object 150′ relative to a corresponding virtual base 120′. The virtual environment may be provided on an external, separate electronic device 160 (not shown in this figure). The system 100 is substantially compact and may, by way of example, be mounted and operated on a surface such as a desk or bench top.

FIG. 1b shows a tracking system according to a second embodiment. Here, a hub or module 121 is optionally provided on or as part of the mat 120, or may be separate from the mat 120. In the latter case, different, interchangeable mats 120 may be provided for use with a hub 121. The mats 120 may be configured differently in terms of the technology used, and/or may be of different aesthetic appearances. A computer generated virtual environment 140 for display on an external computing device is also provided as described with reference to FIG. 1a.

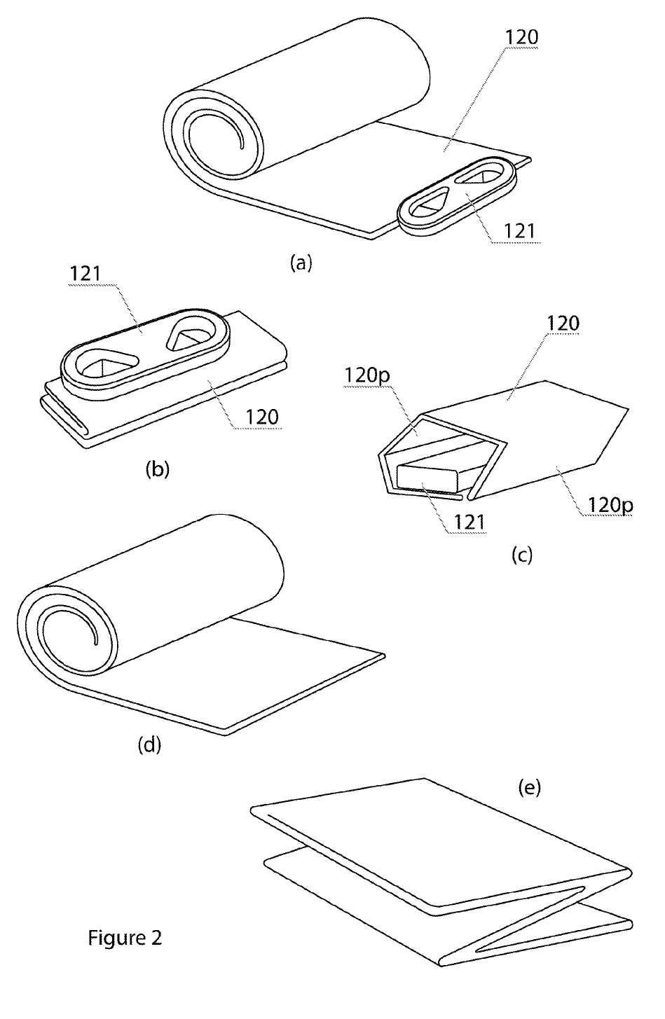

In either embodiment, the mat 120 may be flexible. FIG. 2 shows an example of a mat 120 that is made of a flexible material that permits it to be rolled (FIG. 2a) or folded (FIG. 2b). To achieve this, the mat may be formed of TPE, flexible PCB, a conductive fabric or the like. Alternatively the mat 120 could be formed of solid panels 120p joined by a flexible material of the type mentioned above (FIG. 2c). FIGS. 2d and 2e respectively show a mat 120 rolled and folded in the embodiment where the hub 121 is separate and/or detachable from the mat 120.

Referring again to FIG. 1b, the hub 121 is configured to perform various functions. It can house or support one or more object modules 150a. It can house one or more components configured for communicating with the object modules 150a and/or an external electronic device. These features are discussed in more detail below.

With respect to both embodiments, the base 120 or hub 121 may comprise an integral power source, and/or a compartment for a removable battery, fuel cell or other fuel source to power the hub 121 and/or any object modules 150a docked within it. Rechargeable batteries/fuel cells may be used. The hub 121 may be provided with a power port such as a USB port. It may also/instead have a mains electricity connector. The external power source may allow the hub 121 to recharge the batteries, and/or to provide power to electronic components and devices therein.

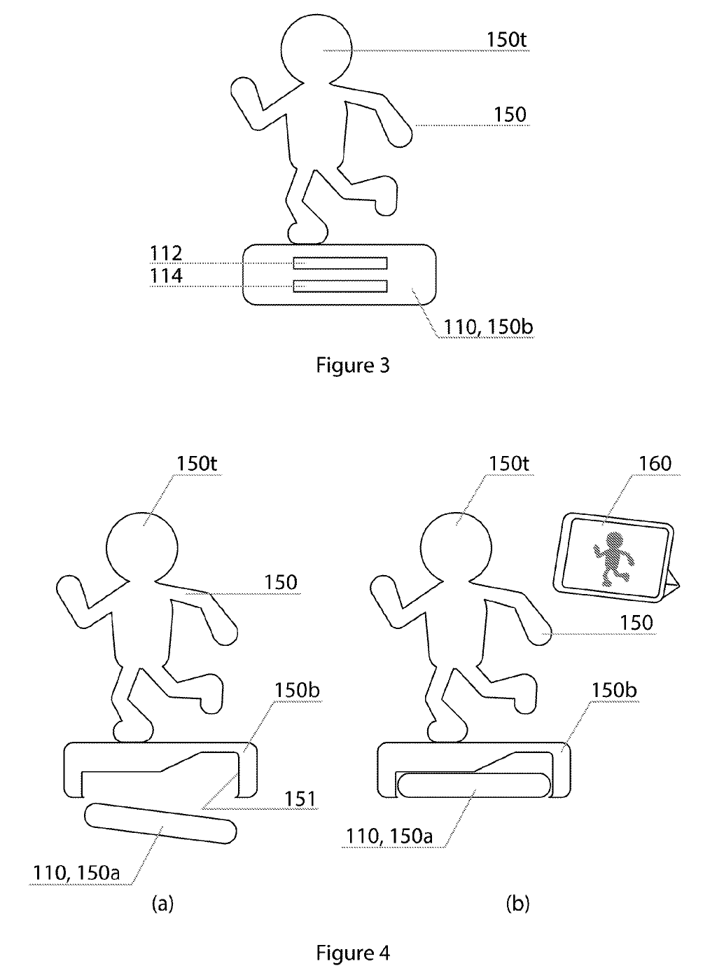

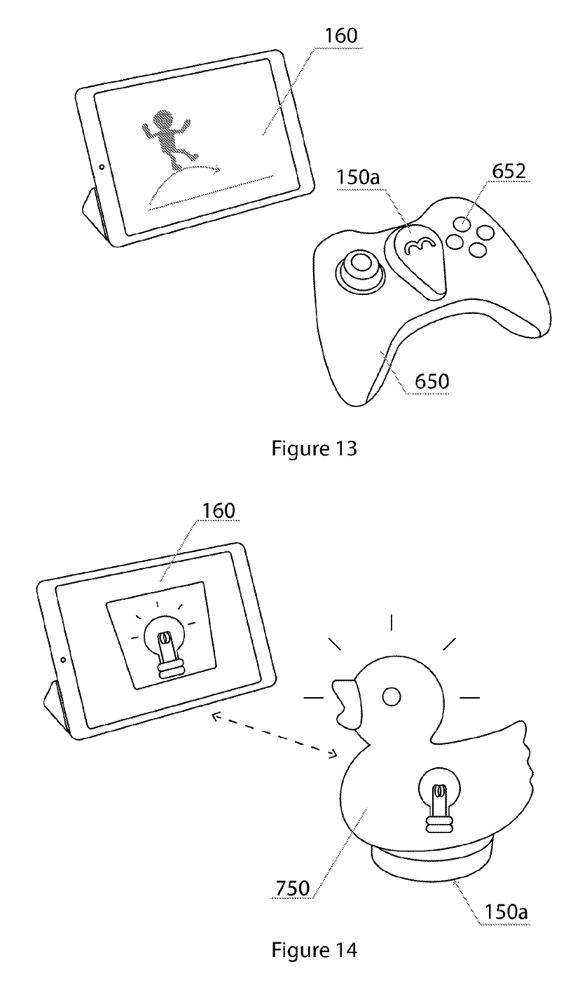

With reference again to the first embodiment, the object 150 is movable relative to the base 120. The object 150 may be or comprise a generic or stylised three-dimensional object. The object 150 may have a shape, model figure and/or may be a toy or a controller (e.g. a games controller such as that shown in FIG. 13). The object 150 may have a flat base (e.g. be or comprise a cuboid or pyramid but could also be profiled e.g. as shown in FIG. 3 or 8b.

The object 150 comprises a magnet 112. In some embodiments, the flat base of the object 150 may advantageously facilitate attachment to the magnet. Alternatively, the magnet 112 may be integral with the object 150. In that case, it is convenient for the object to have a flat surface for standing on the mat 120.

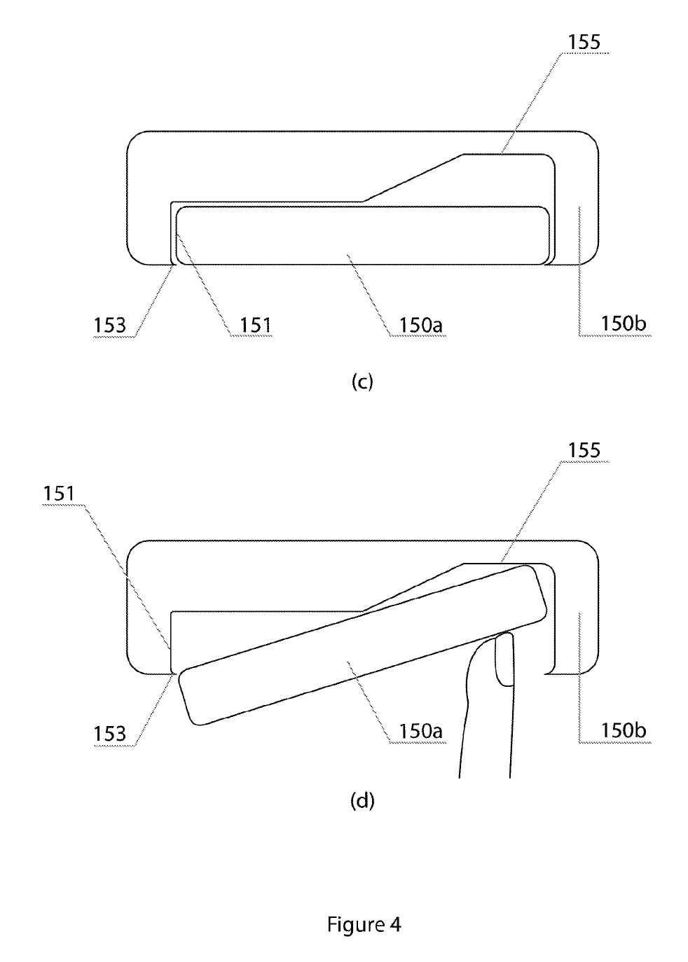

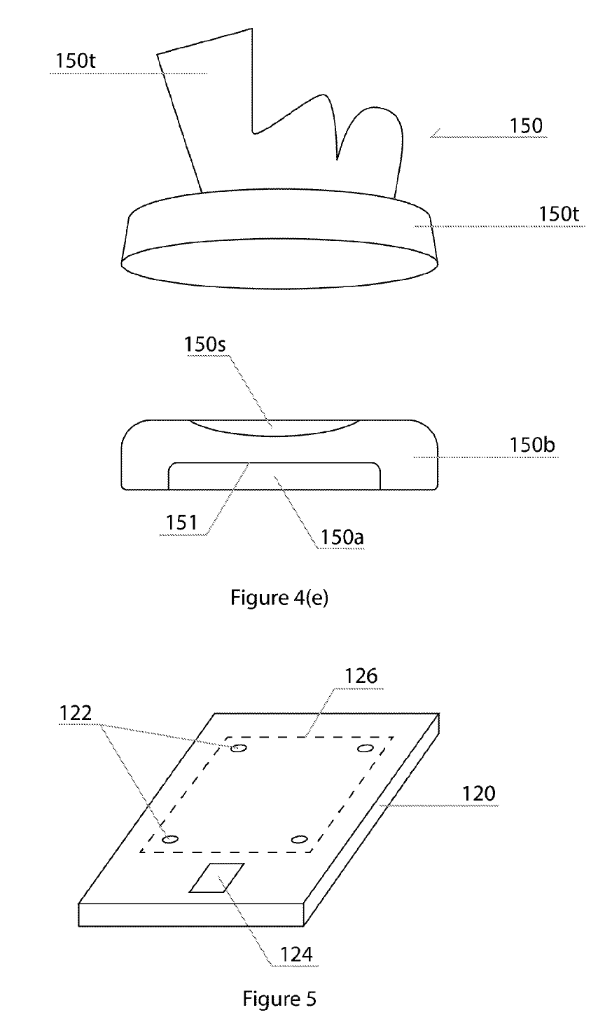

In FIG. 3 the object 150 has a top part 150t and a base 150b. Here the object 150 is shown as a toy and has a shaped top part 150t and a bottom part 150b that is a magnet module 110. The magnet module 110, 150b may be detachable or exchangeable, as in the second embodiment and as discussed further with reference to FIG. 4. Alternatively, the magnet module 110 may comprise the object 150 i.e. they are integrally formed.

The magnet module 110 comprises a source of a magnetic field e.g. a magnet 112. The magnet may be an electromagnet. It may also comprise an identifier 114. An electronic reader 124 may be provided in the base 120 for reading (or scanning in) the object ID stored in the ID tag 114. The electronic reader may be an RFID reader or an NFC reader.

Alternatively, in the second embodiment, the magnet 112 may be housed in a separate object or object module 150a receivable in or on the object 150 (e.g. as in FIG. 4 discussed below). The object module 150a may be detachably attachable to e.g. insertable into the object 150. As for the first embodiment, the object 150 is movable relative to the base 120. In this embodiment, the identifier 114 is provided in the object 150. The reader 124 is provided in the object module 150a. The electronic reader may be an RFID reader or an NFC reader.

For both embodiments, the identifier may be an electronic ID, for example electronic ID may be stored in a radio frequency identification (RFID) tag or a near-field communication (NFC) ID tag. The RFID tag 114 contains information that identifies the object 150. This may be in the form of a code that is unique to that object 150. The ID can be used to identify a virtual character 150′ associated with the object 150. The ID may also include information such as the magnet type and properties. For example, the ID may include properties such as the dimensions and strength of the magnet 112. In the second embodiment, when the object module 150a connects with the object 150 (or other accessory as is discussed below), the reader 124 in the object module 150a reads the object's (or the accessory's) RFID/NFC identity. The object module 150a then takes on certain characteristics or behaviours to replicate in the virtual dimension.

For the second embodiment, FIG. 4(a) shows an example where the object module 150a attaches into a recess 151 provided within the base of the object 150. FIG. 4(b) shows the object module 150a in place within the base of the object 150. When so inserted, the total lower surface provided by the base of the object 150 and the lower face of the object module are preferably flush to form a continuous smooth surface. The recess 151 may be shaped to facilitate retaining the object module 151 in place within the object 150 and allowing removal thereof. FIGS. 4(c) and (d) respectfully show in close-up the object module 150a inserted into the base and being removed therefrom.

To aid retention, the base comprises an inwardly projecting lip 153. The lip 153 is sufficient to narrow the opening of the base to prevent the object module 150a slipping out of position. The base also comprises a cavity 155. In the embodiment shown, the cavity 155 is formed by making the base thinner in a region at an end or side of the base that is opposite to that which comprises the lip 153. As such, the object module 155a is in contact with the thicker part of the base in the vicinity of the lip 153, but not in contact with the thinner part of the base.

The object module 150a can be removed from the base if a user pushes or presses the end of the object module 105a into the cavity 155. The force exerted by the user needs to be sufficient to overcome the resistance offered by the lip 153 but, once exceeded, the other end of the object module 150a passes over the lip 153 and becomes free and the object module 150a is then free and can be removed. The lip 153 can be configured to give an audible noise such as a click when the object module 150a is pushed into placed and/or removed from the base.

FIG. 4e shows another embodiment where a base 150b, comprising a magnet 112 and any other relevant features as have been described, is attachable to an object 150—the top part 150t of the object 150. The top surface 150s of the base 150b may be provided with means for attaching to the top part 150t e.g. by providing adhesive thereon to provide a sticky surface. However, it will be appreciated that other fixing means are also envisaged. Using an object module base 150b in accordance with aspects and embodiments of the invention with a top part that is an RFID-enabled object 150 can enable a user to unlock identity information for that top part 150t. The base 150b/system 150 is therefore retro-compatible and provides a new application or use to existing objects, toys and accessories.

For both embodiments, the object 150 is associated with a virtual object or character 150′ that can be represented in the virtual environment 140. The base 120 can serve as a positional reference for the virtual environment 140, while the object 150 represents a virtual character 150′ to be moved with respect to a virtual base 120′ within the virtual environment 140. As the object 150 is moved across the base 120 e.g. by a user or a robot, its position relative to the base 120 is tracked. Tracking may occur in real time, near real time, or otherwise. Moving the object 150 with respect to the base 120 causes the virtual character 150′ to move around in a corresponding way across the virtual base 120′ in the virtual environment 140. Certain inputs can trigger predefined interactions or behaviour of the virtual character 150′ within the virtual environment 140. For example, by simply moving the object 150 across the base 120 the virtual character 150′ may appear to walk or run, and by lifting the object 150 off the base 120 the virtual character 150′ may appear to jump or fly. The predefined behaviour of the virtual character 150′ is associated with an ID of the object 150, which is discussed below.

One or more objects 150 can be scanned into or recognised by the system 100 at any one time. This is facilitated when electromagnets are used since they can be identified using different frequencies. Their positions relative to the base 120 may be tracked simultaneously. Their virtual characters 150′ may appear in the virtual environment 140. Physical interaction of two objects 150 may cause the corresponding virtual characters 150′ to interact within the virtual environment 140 in a predefined manner. For example, by forcing two objects 150 together, their virtual characters 150′ may appear to fight or compete in the virtual environment 140.

FIG. 5 shows a base 120 having a substantially flat top surface. In use, a flat surface is advantageous for supporting the object 150 in a stationary state when it is not being moved by a user. The base geometry is typically planar, such that the length and width of the base 120 are substantially greater than the depth of the base. Although shown in the Figures as a rectangular slab or mat, the base 120 may take the form of a flat lamella of arbitrary shape. In embodiments, the base 120 may comprise a rigid board or a flexible mat. In an alternative embodiment, the base 120 is not flat, but may be cambered, curved or textured to represent a terrain, for example. The shape of the base may be an aesthetic design choice.

The base 120 (first embodiment) or hub 121 (second embodiment) comprises one or more, and preferably a plurality of sensors 122 operable to measure the strength of the magnetic field emanating from the magnet 112. The sensors 122 facilitate tracking of the object 150/object module 150a, as described in greater detail below. Each sensor 122 provides an output signal that is proportional to the strength of the magnetic field measured at its location on the base 120. The base 120 or hub 121 may be substantially free of magnetic material that may interfere with the sensor outputs. In simple terms, the distance (d) of the magnet 112 (object 150) from a sensor 122 is d=1/(C.SQRT(B)), where C is a constant depending on magnet properties and B is the measured strength of the magnetic field. The actual calculation used/needed may be more complicated, structured to take into account other parameters/factors. If the object 150/object module 150a is moved towards a sensor 122, the sensor 122 detects an increased magnetic field and the output increases. If the object 150/object module 150a is moved away from a sensor 122, the sensor 122 detects a lower magnetic field and the output is correspondingly lower. The maximum distance the object 150/object module 150a can be moved away from a sensor 122 before the output signal drops to zero (or below the output noise floor where detection is not possible) sets a “tracking radius” or “tracking volume” of the sensor 122. The tracking radius/volume is determined by the strength of the magnet 112 and the minimum detectable field of the sensor 122. To avoid “dead areas” where the object 150/object module 150a cannot be tracked, the separation of any two adjacent sensors 122 is chosen to be less than twice the tracking radius of the sensor 122.

Accuracy of the position measurement can be improved by incorporating a gyroscope and/or accelerometer in the object 150 or object module 150a. The combination of magnetic field data from the magnetometer 122 in the mat 120/hub 121, and data from a gyroscope and/or accelerometer in the object module 150a enables very good position detection to occur. This also extends the range of tracking that is possible, as it is possible to continue tracking outside the tracking volume based on the accelerometer and gyroscope data, and then reference back to the magnetic tracking when the object is detectable again. But it will also be appreciated that the position can be determined on the basis of the magnetic field data alone.

In either embodiment, the system 100 can track an object 150 in three dimensions as it is moved through the “tracking volume”. The lateral extent of the tracking volume is limited by the 2D detection area, while the vertical extent (the third dimension) is limited by the detection radius. Additionally, by using data from the gyroscope and accelerometer in the object 150 or object module 150a, tracking past the tracking volume can continue. If the object 150 or object module 150a re-enters or is sensed again within the tracking volume, the sensor tracking can take over again. In any event, gyroscope and accelerometer data can be used the entire time, as discussed, to ensure a higher tracking accuracy.

Tracking is advantageously accurate and reliable because the strength of the magnetic field emanating from the magnet 112 decays with distance away from the magnet 112 in a known and predictable manner, and the sensor 122 has a predictable (and calibrated) magnetic response. For example, the magnetic field produced by the magnet 112 may be modelled as a magnetic dipole with a well-known inverse cube decay. The decay coefficient is a property of the magnet 112 that may be known or may be predetermined, for example by using the calibrated sensors 122 to map the decay of the magnetic field with distance which can be stored and interpolated for use in the system 100. The sensor output can therefore be readily converted into a distance relative to the predetermined sensor location on the base 120. Each sensor 122 provides three distance values (x,y,z). These values are derived from the magnetic field sensed along that particular axis and, based on those values, a vector can be calculated which gives the distance and direction to the tracked object. The position of the object 150 or object module 150a relative to the base 120 or hub 121 is preferably calculated using at least three sensor outputs by the known method of trilateration e.g. by a processor discussed below. Although less accurate, the position may also calculated using just one or two sensor outputs.

Unlike optical tracking systems the magnet tracking system 100 advantageously does not require a clear line of sight between the object 150 and the sensors 122 to track. The system 100 can detect the magnetic field emanating from the magnet 112 or 212 through non-magnetic opaque or solid objects. This advantageously allows the user to hold the object in any way and move the object around the base without interfering with the tracking.

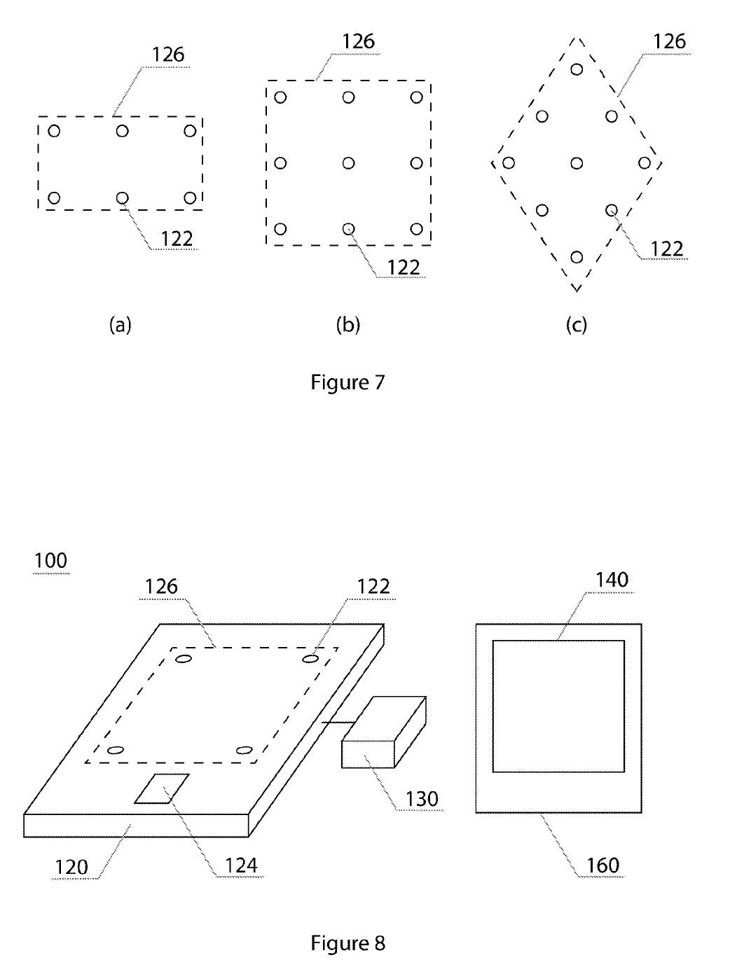

The embodiment of FIG. 5 shows a base 120 comprising an array of four sensors 122 arranged on a rectangular lattice (the rectangular lattice includes the special case of a square lattice). The outer boundary of the array defines a rectangular tracking area 126. In other embodiments, arrays of greater size may be used to increase the tracking area and/or arrays of different geometries may be used, for example a triangular lattice, as illustrated in FIGS. 7 (a)-(c). In other embodiments, fewer or more than four sensors 122 may be used. In an embodiment a single sensor 122 may be used, although the accuracy of identifying the position of the object 150 is improved by using more than one sensor 122. (Note—the reader 124 is provided in the object module 150a in the second embodiment rather than the mat 120, although one or mode additional readers could be provided in the mat in this embodiment.)

In an alternative embodiment, the sensors 122 may be located in the hub meaning the base/mat 120 is not needed at all.

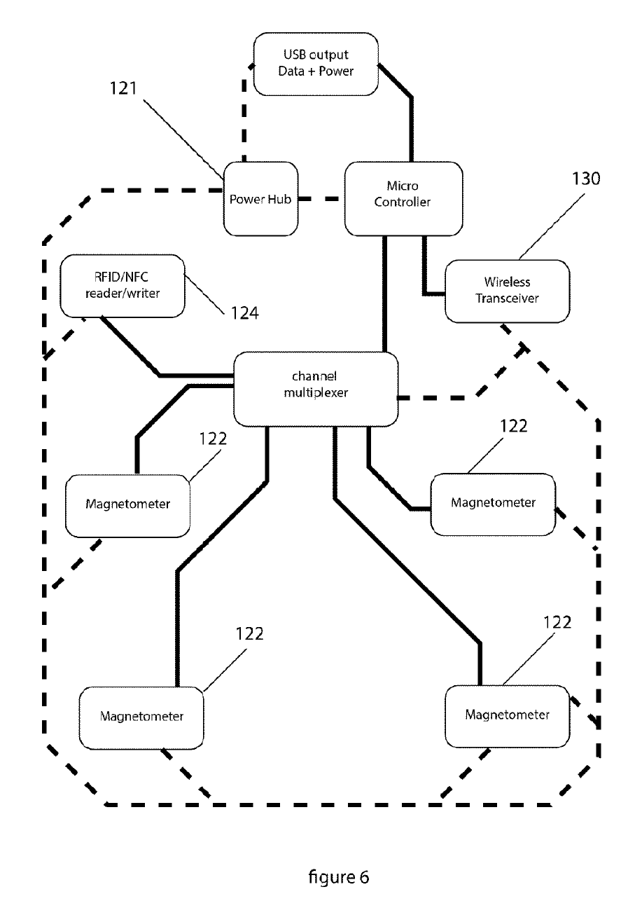

FIG. 6 shows the principal components of a base 120 or hub 121 according to the first or second embodiment of the invention. In the particular embodiment shown, a transceiver 130 is configured to receive outputs from the plurality of sensors 122 and the reader 124, optionally via a multiplexer. The transceiver 130 shown is a radio transceiver, but Bluetooth could be used instead. In other embodiments, e.g. where the sensors 122 can each be given their own, independent addresses, the multiplexer is not needed. If a multiplexer is used, it is controlled by the transceiver 130. When used, the multiplexer allows the transceiver 130 to selectively read data from any of the sensors 122 or the reader 124.

In the second embodiment, to enable communications with the object modules 150a and/or an external electronic device 160, the hub 121 comprises a wireless communications device such as a Bluetooth antenna. It also comprises a processor for performing calculations on data received by the transceiver 130. The hub 121 collects data from the sensors 122, processes it and broadcasts it to other devices e.g. the object modules 150a or the electronic device 160. The device 160 can send data to the object module 150a, and this can be indicated for example by making a light blink, or activating a rumble pack or module present in the object module 150a. The object module may also have one or more other inputs, such as one or more buttons or joysticks that can e.g. allow inputs for games. These inputs, as well as the outputs described above (e.g. blinking LED or rumble pack), are enabled through the communication of the object module 150a with the object 150 either through a hard connection such as pins, or in a wireless manner.

Any such additional hardware may have a chip that allows conversion of any controller inputs (joystick or buttons), into a standardized format, such as 12C. When the object module 150a is plugged into an object 150 such as a controller, a connector (such as a plurality of connector pins) may be provided for transmitting data to the object module 150a. The RFID tag 114 enclosed within such an object/controller 150 can then be used to tell the app how to decipher these inputs, and how this data will be coming in as compared to the standard incoming gyroscope and accelerometer data (see below).

The system can be configured to use different magnets and/or sensors 122 to provide different magnetic field strengths and measurement precision. The sensors 122 can be configured to sense small magnetic fields over short distances and be very useful e.g. in computer aided surgery. In embodiments the strength of the magnet may be in the range approximately 0.05 to 0.6 Tesla (measured at its surface) and the tracking radius may be in the range approximately 5 cm to 30 cm or 40 cm. The resolution of the system may be less than about 1 cm or less than about 0.5 cm (or less than about 0.1 cm). The sensors 122 may be calibrated sensors, allowing the sensor output to be accurately converted to a magnetic field. The magnetic sensors may have a minimum detectable field of less than approximately 50 micro-Tesla.

The magnetic field detectable at the sensor 122 is a vector magnetic field (Bx,By,Bz) containing information that enables the position of the object to be determined in three dimensions (x,y,z). The sensors 122 may be magnetometers. In a preferred embodiment, the sensors 122 are three-axis vector magnetometers operable to measure Bx, By, and Bz. By measuring the magnetic field in the three axes, the system 100 is able to track the position of the object 150 in three dimensions. For example, a user can lift the object 150 or object module 150a away from the top surface of the base 120 or hub 121, as well as move the object 150 or object module 150a across the top surface of the base 120.

FIG. 8 shows an exemplary system 100 for the first embodiment. The transceiver or microcontroller 130 is electrically connected (wired or wireless) to the base 120 (or the hub 121 for the second embodiment). The transceiver 130 is configured to receive the object ID from the reader 124 and outputs from the plurality of sensors 122. Alternatively separate transceivers/controllers 130 may be provided for each. Although shown as a separate element in FIG. 8, in the second embodiment the transceiver 130 may instead be provided within the base 120 or hub 121.

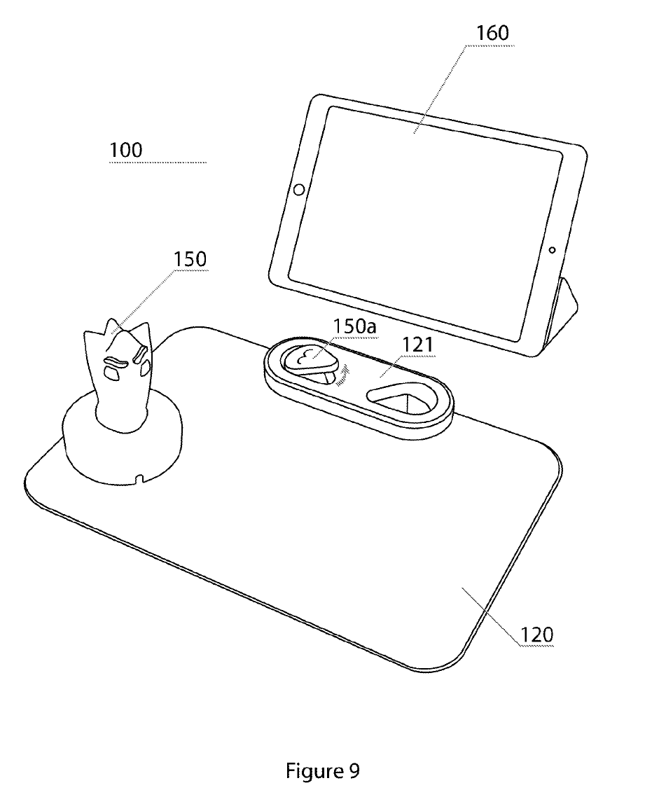

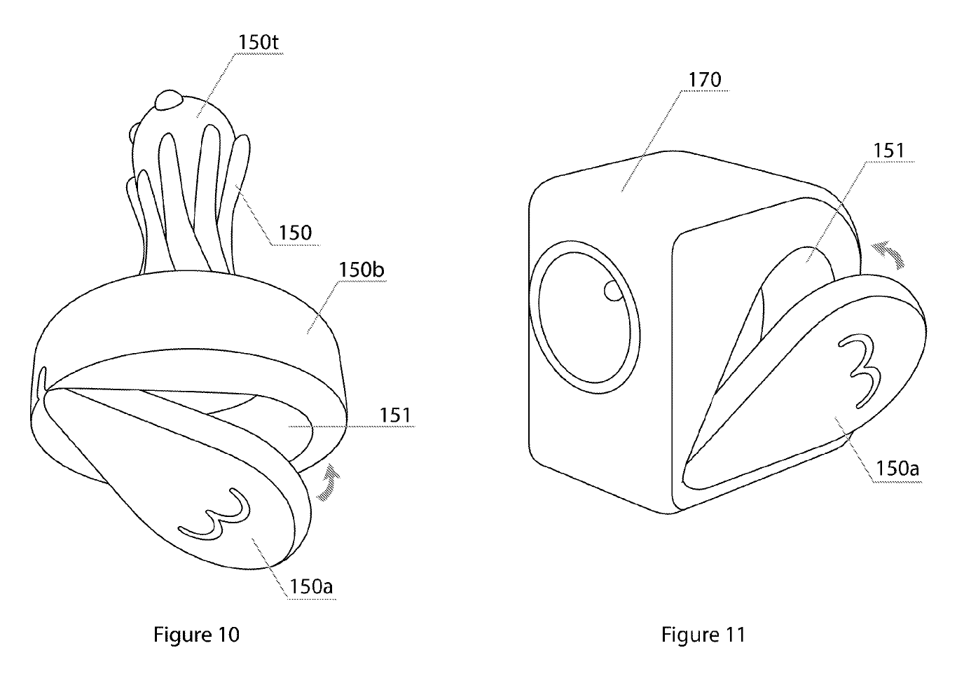

FIG. 9 shows another exemplary system 100 for the second embodiment. Here, the transceiver or microcontroller 130 is integrated into the object module 150a. Data from the object module 15a is transmitted from the object module 150a directly to an electronic device (discussed below). Here, the mat 120 has its own transceiver that sends data to the electronic device.

For either embodiment, an electronic device 160 is provided, e.g. a processor, computer, tablet, iPad, mobile phone or other similar device. The device 160 has a screen or a display on which the virtual environment 140 can be displayed. The device 160 may have a user interface e.g. a GUI. The electronic device 160 may comprise a processor operable to generate the virtual object 150′. The processor is configured to determine the position of the object 150 relative to the base 120, based on the sensor outputs and the predetermined magnet properties contained in the object ID. The processor 130 is operable to determine the position of the object 150 in real time. All of the calculations can occur on the external device 160 e.g. via an app, a programme, or a web application. Using the processing power of the computing device advantageously provides a reduction in the complexity of the system hardware)

The device 160 is configured to receive one or more data streams from the transceiver 130 to generate and display the virtual environment 140. In particular, the electronic device 160 may comprise a display to display the virtual object 150′ associated with the object 150 within the virtual environment 140. The object 150 may appear as one of several different virtual characters 150′ depending on the object ID read from the ID tag 114. For example, the object 150 may appear as a cartoon character, or as an animal or as any other virtual object 150′. The virtual environment 140 may be programmed such that the virtual character 150′ appears to interact with other virtual characters 150′ and/or with other computer-generated elements in the virtual environment. The interactions may manifest in different ways. As the object 150 (including the object module 150a in the second embodiment) is physically moved by a user, the electronic device 160 displays the movement of a corresponding virtual object 150′. The display may be in real time, or there may be a lag.

The one or more data streams may be recorded by the electronic device 160 to generate a visual file for playback. The data file may be edited or shared.

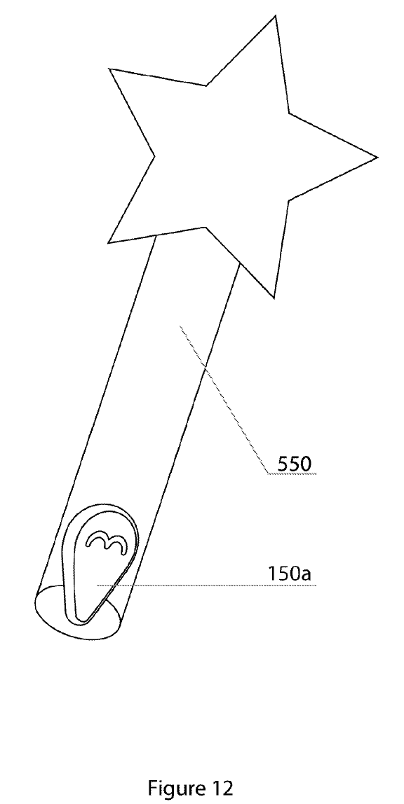

With reference to the second embodiment, FIG. 10 shows an example of an object module 150a being inserted into an object 150. The object 150 here is a toy. The object module 150a may also be inserted into a recess 151 provided in a camera module 170, as shown in FIG. 11. Other objects or accessories for use with the system may be provided, and may have slots or recesses for receiving a tracker. Accessories such as magic wands (FIG. 12), microphones, steering wheels, gamepad controllers (FIG. 13), robots and the like may all be provided and comprise a slot/recess to receive an object module 150a. Such “accessories” are essentially the same as objects 150, but may have one or more additional features such as buttons, touchpads, lights etc. depending on the particular application. These accessories may correspond to individual games or experiences, and these accessories may be used to unlock new functionality or content within the virtual environment.

In FIG. 12, a magic wand 550 is shown with an object module 150a located on and/or on a handle thereof. Such an accessory may be used when playing and interacting with a computer game e.g. to move things around on a screen of an electronic device 160 (not shown).

In FIG. 13, a gamepad controller 650 is shown with an object module 150a located thereon/therein. The gamepad controller 650 is for the most part a standard gamepad controller 650 that operates in a standard way to provide control when playing a game e.g. on an electronic device 160 such as a computing device/tablet/iPad. Pressing a button 652 may cause a character on the screen of the device 160 to perform an action, or otherwise cause something to happen on the screen. Alternatively, the motion detection sensed by the object module 150a is broadcast to the device 160 and used to control what happens on the screen e.g. lifting the controller 650 up may cause a character on the screen of the device 160 to jump up. All of the data from the controller may be sent to the system directly via the object module, so that the controller may not need its own complex electronics such as a Bluetooth.

FIG. 14 shows an example of a slightly different use of an accessory 750. Here the accessory 750 is or comprises a light that can be controlled by an electronic device 160. This exemplifies the two-way communication that exists between the object 150 or accessory 750 and the electronic device 160.

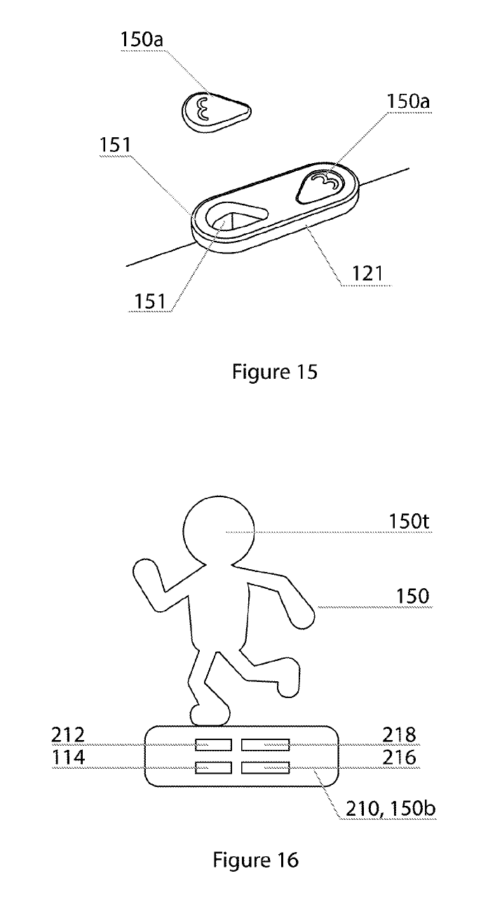

The object modules 150a also fit or click into a recess 151 provided within the hub 121, as shown in FIG. 15. This can provide charging, or an update via hard connections. The components can preferably also/instead be able to update their software wirelessly.

The object module 150a can be configured/programmed to have a sleep mode. This avoids the need for a physical button on the object module 150a to turn it on and off. The system may function as follows:
When the object module 150a is charged and unplugged from the base/mat 120/hub 121, it goes to sleep.
When it is plugged into an object module 150a, the RFID tag causes the reader to respond, waking up the object module 150a.
If the object module 150a is not moved for a predefined time, it will go to sleep, and wake up when moved again.
To avoid the object modules 150a turning on as a result of the motion when transporting them e.g. in a backpack or a vehicle, the object modules 150a can be programmed to enter an off mode when the base/mat 120/hub 121 is unplugged or turned off. During this off mode, the object modules 150a only wake up for a very short time every once in a while to check if the base/mat 120/hub 121 is powered again. This allows the object modules 150a to conserve power and act as if they are completely off.

Whenever an object module 150a is plugged into an object 150, it sends its ID as well as the ID of the object 150 (e.g. toy/controller) that it identified from the RFID tag. The object module 150a sends packets of accelerometer and gyroscope data and/or magnetic data of any accelerometer, gyroscope and/or magnet provided within the object module 150a to the central hub 121/external device 160. If a controller (e.g. 650) is attached to the object module 150a, this data is included in the data stream.

To receive data, the external device 160 (e.g. the tablet/computer) sends a prompt to each object module 150a in sequence to activate the on-board electromagnet 112. The object module 150a then executes this command without the need to send a prompt back. The electromagnet 112 turns on/off (flashes) for a predefined period of time.

FIG. 16 shows another object 150 comprising an exemplary magnet module 210 in accordance with the first embodiment. The magnet module 210 comprises an electromagnet 212. The magnet module 210 further comprises a microcontroller 216 and a switching element 218 to control the power delivered to the electromagnet 212. The switching element 218 may be a transistor, e.g. a power transistor. The microcontroller 216 is in data communication with the transceiver 130 and is operable to control the switching element 218 based on a command signal received from the transceiver 130. For example, the transceiver 130 may request information on the position of the object 150 by sending a “locate” command to the microcontroller 216 to operate the switching element 218 to power the electromagnetic 212 “ON” for a period of time. This reveals the position of the object 150. The microcontroller 216 then operates the switching element 218 again to power the electromagnet 212 “OFF”. The electromagnet 212 may be cycled from “ON” to “OFF” rapidly and the locate command repeated periodically at high frequency to improve the accuracy of the tracking. A duty cycle of less than 50% is preferable to avoid overheating. The “ON” period may be chosen from a range of 0.5 s to 11 ms. The magnet module 210 and the transceiver 130 may be in wired or wireless communication.

In either embodiment, the electromagnet 112 can be used under AC operation, where different objects 150 or object modules 150a are programmed to operate at different frequencies simultaneously. The data from the sensors can then be filtered (for example by a band pass filter), to determine the locations of particular object modules. Alternatively, under DC operation, the magnets 112 are simply turned on and off in sequence so that they can be sensed by the sensor(s) 122 independently. The duty cycle of the on/off sequence can be varied in duration depending on the number of objects/object modules to be sensed. This electromagnet flashing can be controlled by a signal received from the external device.

In either embodiment, the transceiver 130 may comprise embedded code that works as follows:
initialize the components
Calibration (offset null): run a first round of data collection In order to measure the current magnetic field and subtract it from the rest of the following data collection. This is done to only measure the magnetic field disruption generated by the object 150 and base 120.
The rest of the process is based on retrieving data from the magnetometers 122. The system then performs processing of the retrieved data if necessary. Where a multiplexer is used, the following loop repeats:
   Open the gates on the multiplexer and collect XYZ value from each sensor
   Operation on the XYZ value from magnetometers result XYZ is stored into a string
   Optionally, open another gate on the multiplexer and collect data from RFID reader/writer 124 if the ID reader is not located in the object 150. If a tag is detected its UDID is analyzed, and if it matches the catalog a string is stored corresponding to the ID
   Read incoming data on a wireless receiver 130, e.g. Bluetooth or radio transceiver; the Yaw Pitch Roll data coming from an object 150, object module 150a, camera or other accessory is stored in a string “Yaw,Pitch,Roll” as well as the button state on the camera.
   A string is constructed with the following structure: “X,Y,Z, Yaw,Pitch,Roll, RFID” Optional additional input indicators may also be included e.g. button state joystick or other input if used
   the string may be sent to the electronic device 160 (laptop, ipad, macbook, pc, pc tablet, pc desktop . . . ) via the usb serial in order to be read by the electronic device. Alternatively, each of the objects 150 can communicate with the external device 160 independently and send it their data, without the need for that data to go through the hub first. Sending all the data through the hub facilitates timing all the data, while sending everything to the external device directly allows for a much faster communication as the data does not have to be received and then sent again by the hub.

In an embodiment, two or more magnet modules 210 associated with objects 150 are scanned into the system 100 to be tracked simultaneously. The transceiver 130 sends “locate” commands to each of the magnet modules 210 sequentially, such that the “ON” periods associated with each magnet module 210 do not temporally overlap. This ensures that only one electromagnet 212 is powered ON at any one time, to maintain the accuracy of the tracking. Within the “ON” period associated with each magnet module 210, outputs from the plurality of sensors 122 are read by the transceiver 130 and the exact position of the object 150 relative to the base 120 is determined before cycling to the next magnet module 210. However, as mentioned previously, this can also be overcome with the AC (alternating current) method. This can also be done in the second embodiment, to determine the position of the object module 150a relative to the hub 121.

In embodiments, therefore, the object 150 or the object module 150a comprises a magnet 112 or an electromagnet 112 that emits a magnetic field. Their position in 3D space is determined relative to one or more sensors (magnetometers) 122 within the mat 120 (or hub 121). The inclusion of a gyroscope within the object 150 or object module 150a also enables the orientation and/or the pitch, yaw and roll of the object 150 or object module 150a to be determined. The sensors 122 are in predefined locations, and the strength of the magnetic field detected from the magnet/electromagnet in the object 150 or object module 150a provides a measure of the distance of the object 150/object module 150a from the sensor 120. For that reason, using two or more sensors 120 provides more accurate measurements, but a single sensor will still work. The inclusion of an accelerometer provides a measure of the acceleration of the object 150/object module 150a, which again helps to provide an accurate picture of how the object 150/object module 150 is moving.

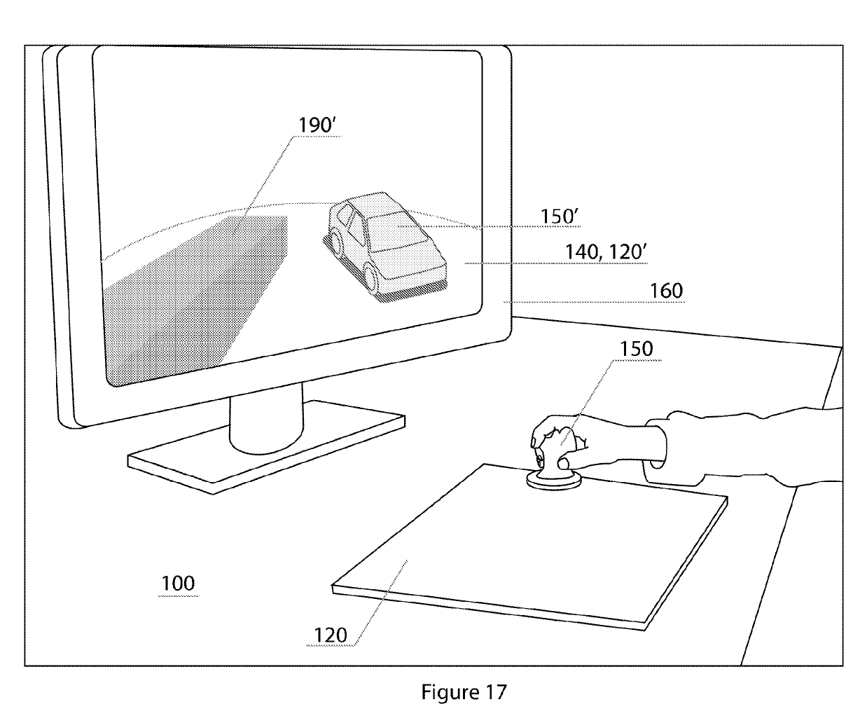

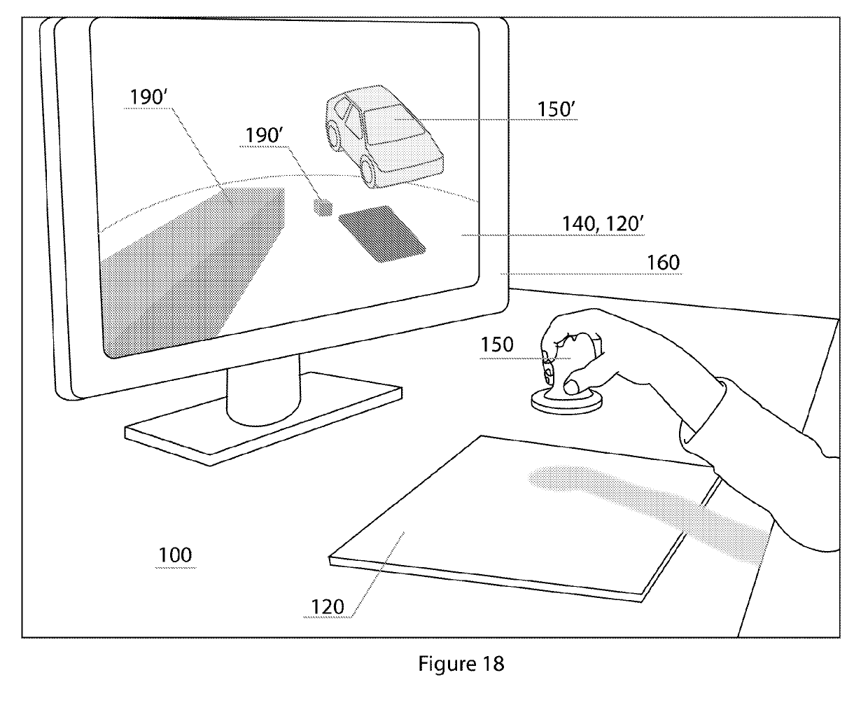

FIG. 17 shows a prototype system 100. Here, an object 150 is represented virtually as a car 150′. In FIG. 18, the user has lifted the object 150 such that it is vertically separated from the base 120. The virtual representation 150′ is correspondingly lifted with respect to the virtual base or terrain 120′. For both FIGS. 17 and 18, additional virtual objects 190′ are visible. Even though no corresponding physical object is present, if the virtual representation 150′ interacts with the virtual obstacles 190′ within the virtual environment 140, the virtual representation 150′ and/or the virtual obstacles 190′ will react in accordance with preprogrammed rules.

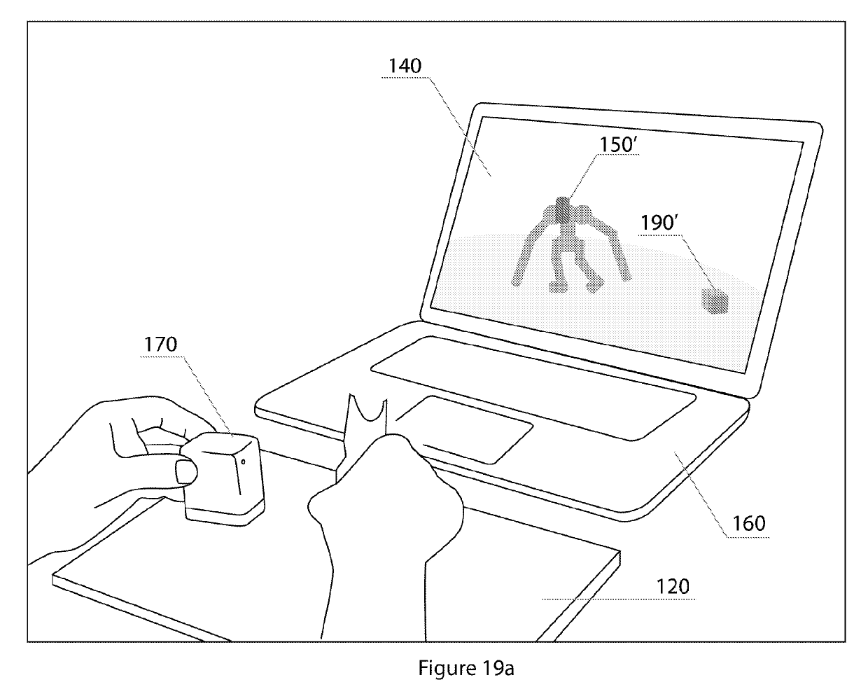

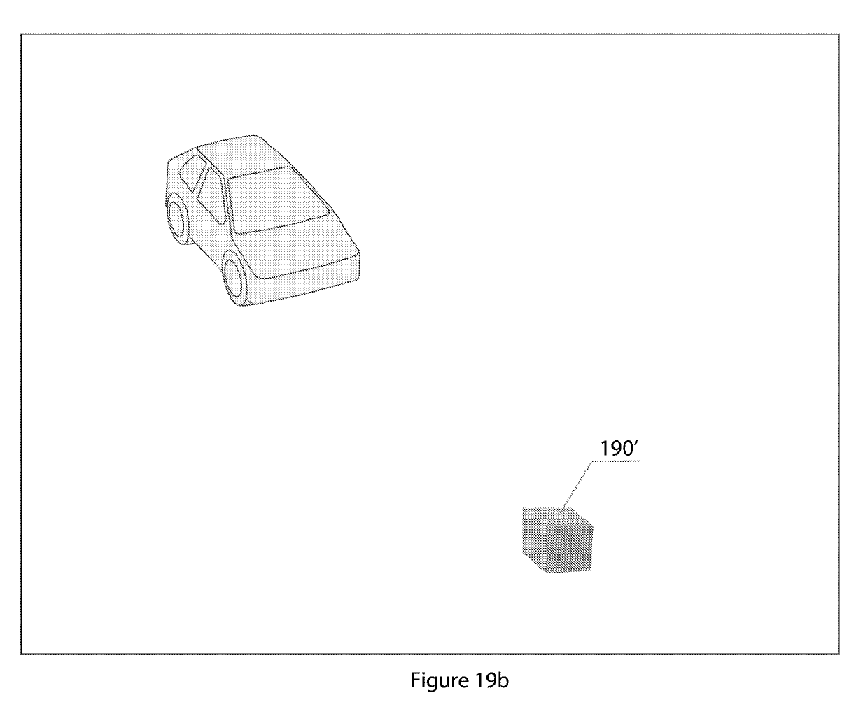

In the embodiment shown in FIG. 19a, the system 100 further comprises a camera module 170 and/or a microphone to provide supplementary inputs to the virtual environment. The one or more data streams transferred to the transceiver may also include a camera data stream and/or a microphone data stream, as discussed in more detail below.

The camera module 170 may be a physical device in data communication with the transceiver 130 (as shown in FIG. 19a) or a virtual camera module 170′ that is displayed or represented at device 160 e.g. in the user interface. The virtual environment 140 is altered by changing the angle and/or position of the camera module 170, either by physically moving the camera module 170 or by moving it in the virtual environment 140 via the user interface. The physical camera module 170 is moveable and can be positioned anywhere on or around the base 120, and is trackable in 3D space just like an object 150. The camera module 170 may also/instead be positioned in predetermined locations on the base so that its position is known. The physical camera module 170 may comprise a microcontroller and an inertial measurement unit (IMU). When the camera module is physically moved, the movement is analysed by the IMU and camera data is sent to the transceiver 130. In embodiments, the camera module 170 may further comprise a magnet 112 to enable the system 100 to determine the position of the camera module 170 relative to the base. The camera data stream comprises the position of the camera relative to the base and gyroscopic data, also referenced as yaw, pitch and roll of the IMU to provide a point of view and perspective for the virtual environment 140. In other embodiments, the camera module is in wireless data communication with the transceiver 130, wherein camera data are sent wirelessly to the transceiver 130 via an RF transceiver in the camera module. The camera can directly communicate with the computer as mentioned previously, but also can be designed so the IMU and magnet are in the object.

In embodiments, the point of view and perspective of the virtual display can be fixed or chosen from one several preset positions and angles from within the user interface. FIG. 19b shows an example of a generated virtual environment 140 in the case where the object 150 is lifted up above the camera module 170 in 3D space. In contrast to the camera angles of FIGS. 17 and 18, in FIG. 19b the camera is virtually below the virtual representation 150′ looking up at the virtual representation 150′.

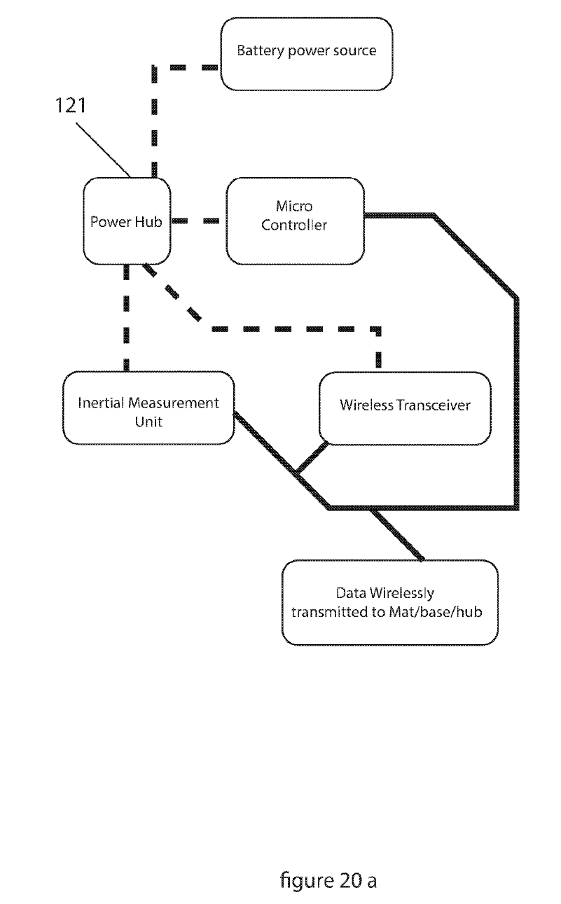

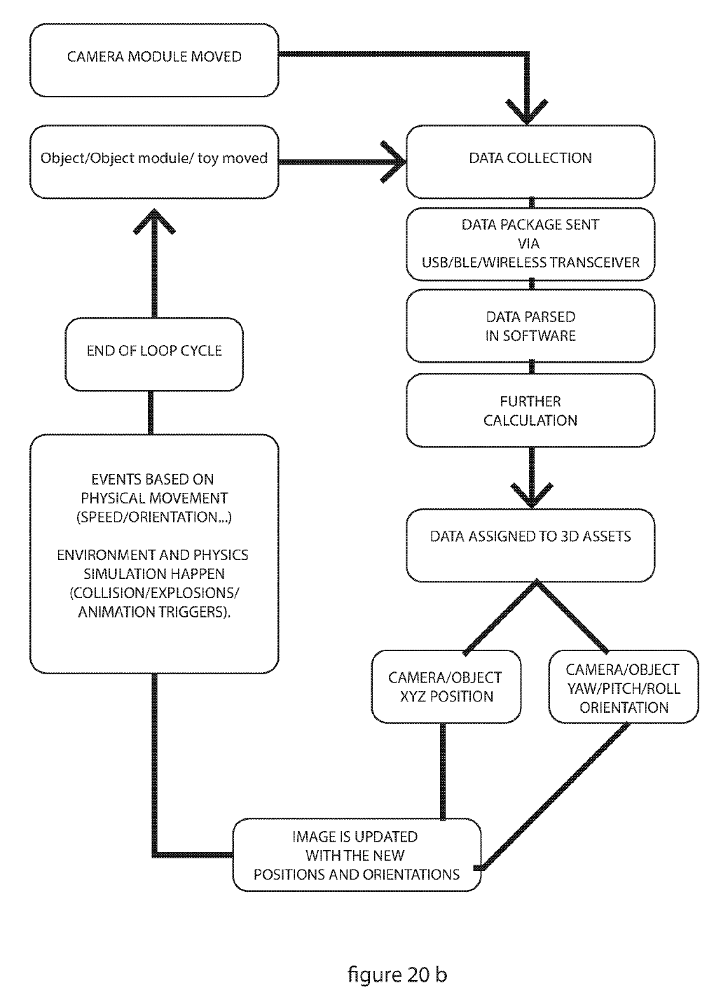

FIG. 20a shows the principal circuit components of the camera module 170. FIG. 20b illustrates steps involved in using the camera module 170 in conjunction with the tracking system 100 to generate a virtual environment 140. The camera module 170 can directly communicate wirelessly with the external device. It should be noted that this Figure shows the principal circuit components of a standalone camera module accessory, but any kind of accessory could be configured in this way. Alternatively, the camera module or any other accessory could be designed using the external tracker.

Alternatively, the data is sent wirelessly to the external device 160. This can happen such that, in the second embodiment, the hub 121 accumulates all the data from the object(s) 150 and then sends it to the external device, or in a way where all the objects communicate independently with the external device 160.

The microphone may be provided in the base 120, or the transceiver 130 or base 120 may comprise a microphone connector input. Alternatively, the microphone in the external device may be used directly. The microphone data provides sound effects for the virtual environment that are added to the generated virtual environment 140, such as user voices, commentary or music. The sound may be used as a user input to trigger certain behaviour or interactions of the virtual characters 150′ within the virtual environment 140 such as facial gestures to simulate speech. The microphone data stream may be recorded along with the visual data to generate an audio-visual file for playback.

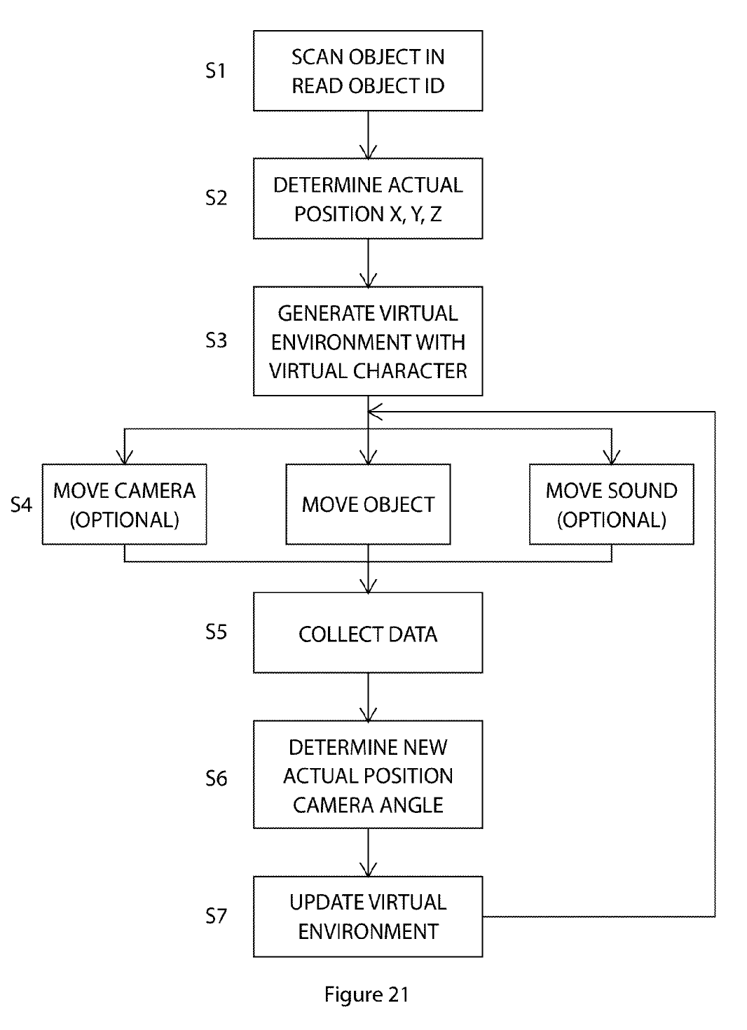

FIG. 21 shows a flow diagram illustrating a method of tracking the position of an object relative to a base. In step S1, an object 150 is scanned by the reader 124 and the object ID 114 is read (because now the RF readers are embedded inside the trackers that click into the toy. The actual position (co-ordinates) of the object 150 is determined in step S2. In step S3, a virtual environment 114 is generated with virtual characters 150′ and/or virtual objects 190′.

In embodiments, the XYZ and pitch roll and yaw can be obtained for the object 150/object module 150a, camera or other accessory.

In step S4, a user moves the object 150. The user may provide one or more other inputs e.g. via one or more buttons or joysticks that can e.g. allow inputs for games. Optionally the camera 170 may be moved and/or the user may make a sound into the microphone, if present. Data from step S4 is collected at step S5. At step S6, the position and camera angle is determined. The virtual environment 140 is updated at step S7 and an updated representation is made on device 160.

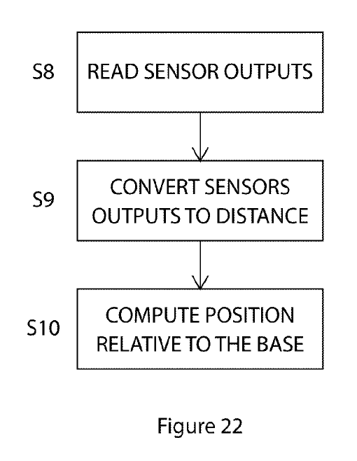

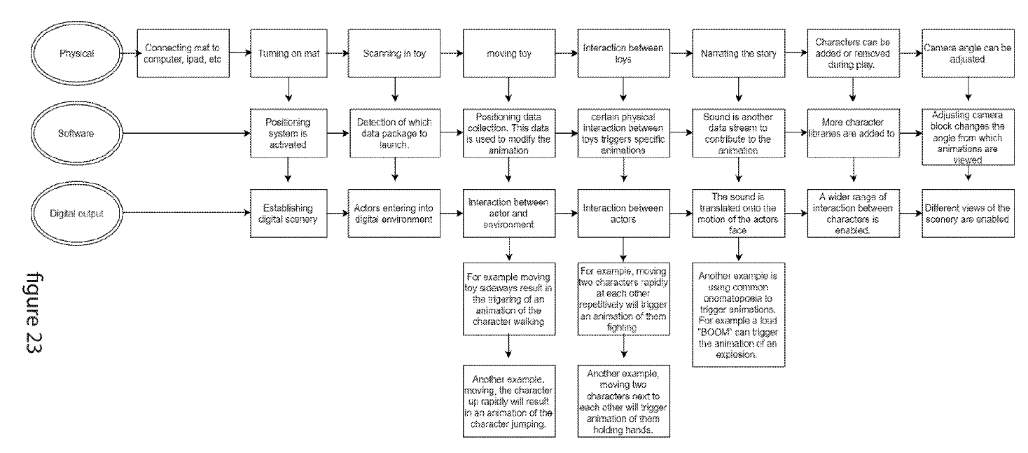

FIG. 22 shows a flow diagram illustrating a method of determining the position of the object 150 relative to a base. In step S8 outputs from the sensors 122 are read. In step S9 the outputs of the sensors 122 are converted into a distance relative to the sensors based on the object ID 114. In step 10, the position of the object 150 relative to the base 120 is computed using trilateration.

FIG. 23 shows an overall summary of the key steps in the above defined processes, divided into “physical” interactions, “software” interactions and “digital outputs” and the interactions between them. It should be noted that this is a breakdown of how this system would work for the specific case of using this system for the creation of 3D animations, but that it can equally be used for a variety of other applications. For example, an animation app may be utilised. The output may be a 360° video which may be viewed with a VR headset. This provides a new form of interacting with VR content in a less immersive way where, instead of wearing a headset you navigate through the environment with a tangible object, and can interact with the environment with a set of tools (real or virtual objects). Actually interacting with games and various other VR experiences is also contemplated.

FIGS. 17-23 are generally shown and described with reference to the first embodiment, but it will be appreciated that the features described also apply to the second embodiment.

Although the appended claims are directed to particular combinations of features, it should be understood that the scope of the disclosure of the present invention also includes any novel feature or any novel combination of features disclosed herein, either explicitly or implicitly or any generalisation thereof, whether or not it relates to the same invention as presently claimed in any claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable sub-combination.

For the sake of completeness it is also stated that the term “comprising” does not exclude other elements or steps, the term “a” or “an” does not exclude a plurality, and any reference signs in the claims shall not be construed as limiting the scope of the claims.

1. A method for tracking a position of an object, the method comprising:
receiving magnetic field data from one or more sensors disposed within a base, the sensors being configured to detect a magnetic field emanating from a magnet on or within the object;
determining an actual position of the object relative to the base based on the magnetic field data from the sensors;
generating a corresponding virtual position of the object based on the magnetic field data; and
displaying the virtual position electronically.

2. The method of claim 1, further comprising:
generating a virtual environment comprising a virtual base corresponding to the base; and
displaying, in the virtual environment, a corresponding virtual object at the generated virtual position relative to the virtual base.

3. The method of claim 2, further comprising:
reading an electronic identification associated with the object and generating a signal representative of a corresponding identification of the virtual object; and
displaying the virtual object having one or more unique characteristics based on the signal representative of the identification of the virtual object.

4. (canceled)

5. The method of claim 2, wherein one or more of generating the virtual object or the virtual position of the object is performed in real time or near real time, or otherwise.

6. The method of claim 1, further comprising, when the object is moved relative to the base, determining a new actual position of the object relative to the base and updating the virtual position of the virtual object relative to the virtual base.

7. A system for tracking the position of an object, the system comprising:
an object comprising a magnet;
a base comprising one or more sensors for detecting a magnetic field emanating from the magnet;
a receiver or transceiver configured to receive and output magnetic field data from the sensors; and
software for determining, based on the output magnetic field data, an actual position of the object relative to the base and generating a corresponding virtual position for displaying electronically.

8. The system of claim 7, wherein the magnet is comprised in an object module that is insertable into and removable from the object;
the object further comprises an electronic identification and the object module comprises a first reader for reading the electronic identification of the object; and
the base further comprises a second reader for reading the electronic identification.

9. (canceled)

10. (canceled)

11. The system of claim 7, wherein the magnet comprises an electromagnet.

12. The system of claim 11, wherein the object or object module further comprises a microcontroller and a switching element operable to control electrical power delivered to the electromagnet;
the microcontroller is in data communication with one or more of the transceiver or an external computing device; and
the microcontroller is operable to control the switching element based on commands received from one or more of the transceiver or the external computing device.

13. The system of claim 12, wherein one or more of the transceiver or the external computing device is in wireless data communication with one or more of the microcontroller of the object and the object module.

14. (canceled)

15. The system of claim 8, wherein the electronic identification is either a radio frequency electronic identification (RFID) or near field communication (NFC) identification.

16. The system of claim 7, wherein the sensors are arranged to and are operable for determining the position of the object in three dimensional space.

17. The system claim 16, wherein the magnetic field data received from the sensors comprises a three dimensional magnetic field vector.

18. (canceled)

19. The method of claim 1, further comprising recording tracking of the virtual object on a display.

20. An object module for use in a system for tracking a position of an object, the object module comprising:
a magnet;
an identification reader for reading an electronic identification of the object;
a wireless communications device for communicating with one or more of the object or an external device;
an accelerometer; and
a gyroscope.

21. The object module of claim 20, further comprising a magnetometer for sensing a magnetic field from a second magnet of a second object module.

22-25. (canceled)

26. The method of claim 1, wherein displaying the generated virtual position electronically comprises displaying the generated virtual position on a display of an electronic device.

27. The method of claim 1, wherein the sensors are arranged to and are operable for determining the position of the object in three dimensional space.

28. The method of claim 27, wherein the magnetic field data received from the sensors comprises a three dimensional magnetic field vector.

29. The method of claim 28, wherein determining the actual position of the object relative to the base based on the magnetic field data from the sensors comprises:
converting the magnetic field data from the sensors into a three dimensional position vector relative to the position of the sensors; and
calculating the position of the object relative to the base using one or more of multilateration and trilateration, when more than one sensor is used.
